(19) United States
(12) Patent Application Publication
(10) Pub. No.: US 2015/0358018 A1
(43) Pub. Date: Dec. 10, 2015

(54) GATE DRIVING CIRCUIT AND DISPLAY DEVICE HAVING THE SAME

(71) Applicant: Samsung Display Co., LTD., Yongin-City (KR)

(72) Inventors: Hyun-Joon KIM, Yongin-si (KR); Jong-Hee KIM, Hwaseong-si (KR); Jae-Keun LIM, Suwon-si (KR)

(21) Appl. No.: 14/542,292

(22) Filed: Nov. 14, 2014

(30) Foreign Application Priority Data
Jun. 10, 2014 (KR) 10-2014-0070245

(51) Int. Cl. H03K 17/284; G09G 3/20; H03K 17/22; H03K 17/687; H03K 17/693

(52) U.S. Cl. CPC H03K 17/284; H03K 17/6871; H03K 17/693; H03K 17/223; G09G 3/2096; G09G 2310/08; G09G 2310/0243; G09G 2300/0814; G09G 2300/0819; G09G 2320/0613

(57) ABSTRACT

A gate driving circuit including a plurality of gate driving units respectively coupled to a plurality of gate lines, each of the plurality of gate driving units includes a carry unit configured to output a carry signal, a pull-up unit configured to output a gate signal, and a pull-down unit configured to pull down an output node of the gate signal. The frequency control signal is configured to controlling a frequency of outputting the gate signal

### CROSS-REFERENCE TO RELATED APPLICATION(S)

This application claims priority under 35 USC §119 to Korean Patent Applications No. 10-2014-0070245, filed on Jun. 10, 2014 in the Korean Intellectual Property Office (KIPO), the contents of which are incorporated herein in its entirety by reference.

### BACKGROUND

1. Technical Field

Example embodiments relate generally to a display device. More particularly, embodiments of the present inventive concept relate to a gate driving circuit and a display device having the gate driving circuit.

2. Description of the Related Art

A display device includes a display panel, a data driving circuit, a gate driving circuit, and a timing controller. The display panel includes a plurality of gate lines and a plurality of data lines. The gate driving circuit provides a gate signal to the plurality of gate lines. The data driving circuit provides a data signal to the plurality of data lines.

The gate driving circuit includes a plurality of gate driving units. Gate driving units are coupled to the respective gate lines. Further, the gate driving units are coupled to each other. The gate driving units sequentially output the gate signal in response to a gate clock signal. Each of the gate driving units outputs the gate signal that has the same frequency.

### SUMMARY

Some example embodiments provide a gate driving circuit capable of sequentially outputting a gate signal.

Some example embodiments provide a display device having the gate driving circuit.

According to an aspect of example embodiments, a gate driving circuit including a plurality of gate driving units respectively coupled to a plurality of gate lines, each of the plurality of gate driving units including a carry unit configured to output a carry signal, a pull-up unit configured to output a gate signal in response to a frequency control signal, the frequency control signal including a first pulse having an on-voltage during a first enable period and a second pulse having an on-voltage during a second enable period that is different from the first enable period, the first pulse being repeated in a first cycle, and the second pulse being repeated in a second cycle that is different from the first cycle, the frequency control signal being configured to controlling a frequency of outputting the gate signal; and a pull-down unit configured to pull down an output node of the gate signal.

In example embodiments, the second enable period of the second pulse may be shorter than the first enable period of the first pulse and the second cycle of the second pulse may be shorter than the first cycle of the first pulse.

In example embodiments, the first enable period of the first pulse may be equal to or shorter than a frame period, and the first cycle of the first pulse may be longer than a frame cycle.

In example embodiments, the gate signal may be output in a first output period having substantially the same width as the first enable period and in a second output period having substantially the same width as the second enable period, the first output period is delayed by a predetermined first time period from a start timing of the first enable period, and the second output period is delayed by the predetermined first time period from a start timing of the second enable period.

In example embodiments, the frequency control signal may have an on-voltage when the gate clock signal has the on-voltage.

In example embodiments, the pull-up unit may include a first transistor having an input electrode that receives a gate clock signal and an output electrode that outputs the gate signal, and a second transistor having an input electrode coupled to a first node and an output electrode coupled to a gate electrode of the first transistor, the second transistor being configured to output a voltage of the first node to the gate electrode of the first transistor in the first and second enable periods in response to the frequency control signal.

In example embodiments, the pull-up unit may further include an initialization transistor having an input electrode coupled to the gate electrode of the first transistor, an output electrode coupled to a low voltage line, and a gate electrode that receives a carry signal from a subsequent gate driving unit, and the initialization transistor initializes the gate electrode of the first transistor to a low voltage in response to the carry signal from the subsequent gate driving unit.

In example embodiments, the gate driving unit may further include a pull-up control transistor having an input electrode that receives the carry signal from a previous gate driving unit, an output electrode coupled to the first node, and a gate electrode coupled to the input electrode of the pull-up control transistor, and the pull-up control transistor charges the first node to an on-voltage of the carry signal from a previous gate driving unit in response to the carry signal from a previous gate driving unit.

In example embodiments, the carry unit may include a third transistor having an input electrode that receives a gate clock signal, an output electrode that outputs the carry signal, and a gate electrode coupled to a first node, and a first capacitor disposed between the gate electrode of the third transistor and the output electrode of the third transistor.

In example embodiments, the pull-down unit may include a fourth transistor having an input electrode coupled to a first node, an output electrode coupled to a low voltage line, and a gate electrode that receives the carry signal from a subsequent gate driving unit, the fourth transistor configured to pull down the voltage of the first node to a low voltage in response to the carry signal from a subsequent gate driving unit, the fifth transistor having an input electrode coupled to the output electrode of the first transistor, an output electrode coupled to the low voltage line, and a gate electrode that receives the carry signal from a subsequent gate driving unit, the fifth transistor configured to pull down the on-voltage of the gate signal to an off-voltage in response to the carry signal from a subsequent gate driving unit.

According to an aspect of example embodiments, a display device may include a display panel having a plurality of gate lines, a plurality of data lines, and a plurality of pixels coupled to the plurality of gate lines and the data lines, the display panel including a first display area that is driven at a first frequency and a second display area that is driven at a second frequency that is different from the first frequency, a data driving circuit coupled to the data lines, the data driving circuit being configured to provide data signals to the data lines, a timing controller configured to control the data driving circuit, and to generate a frequency control signal and a gate clock signal, the frequency control signal including a first pulse having an on-voltage during a first enable period and a second pulse having an on-voltage during a second enable period that is different from the first period, the first pulse being repeated in a first cycle, and the second pulse being repeated in a second cycle that is different from the first cycle, and a gate driving circuit configured to receive the gate clock signal and the frequency control signal from the timing controller, to provide the first display area with a first gate signal with the first frequency based on the gate clock signal and the first pulse of the frequency control signal, and to provide the second display area with a second gate signal with the second frequency based on the gate clock signal and the second pulse of the frequency control signal.

In example embodiments, the second enable period of the second pulse may be shorter than the first enable period of the first pulse, and the second cycle of the second pulse may be shorter than the first cycle of the first pulse.

In example embodiments, the first enable period of the first pulse is equal to or shorter than a frame period, and the first cycle of the first pulse may be longer than a frame cycle.

In example embodiments, the first gate signal may be output in a first output period having substantially the same width as the first enable period, the second gate signal may be output in a second output period having substantially the same width as the second enable period, the first output period is delayed by a predetermined first time period from a start timing of the first enable period, and the second output period is delayed by the first time period from a start timing of the second enable period.

In example embodiments, the timing controller may generate the frequency control signal having an on-voltage when the gate clock signal has the on-voltage.

In example embodiments, the gate driving circuit includes a plurality of gate driving units, each of the plurality of gate driving units may include a carry unit configured to charge a first node in response to a carry signal from a previous gate driving unit and configured to output a carry signal, a pull-up unit configured to output the gate clock signal as the first or second gate signal in response to the frequency control signal, and a pull-down unit configured to pull down an output node of the gate signal to an off-voltage in response to a carry signal received from a subsequent gate driving unit.

In example embodiments, the pull-up unit may include a first transistor having an input electrode that receives the gate clock signal and an output electrode that outputs a first or second gate signal, and a second transistor having an input electrode coupled to the first node and an output electrode coupled to a gate electrode of the first transistor, the second transistor configured to output a voltage of the first node to the gate electrode of the first transistor in the first and second enable periods in response to the frequency control signal.

In example embodiments, the pull-up unit may further include an initialization transistor having an input electrode coupled to the gated electrode of the first transistor, an output electrode coupled to a low voltage line, and a gate electrode that receives the carry signal from the subsequent gate driving unit and the initialization transistor initializes the gate electrode of the first transistor to a low voltage in response to the carry signal from the subsequent gate driving unit.

In example embodiments, the Nth gate driving unit may further include a pull-up control transistor having an input electrode that receives the carry signal from the previous gate driving unit, an output electrode coupled to the first node, and a gate electrode coupled to the input electrode of the pull-up control transistor, the pull-up control transistor charges the first node to the on-voltage of the previous carry signal in response to the carry signal from the previous gate driving unit.

In example embodiments, the display device may further include an area determination unit determining the first display area and the second display area based on a picture data, the timing controller may receive an area determination signal from the area determination unit and generate the frequency control signal.

Therefore, a gate driving circuit according to example embodiments may output a plurality of gate signals of which a frequencies are different from each other based on a frequency control signal. Thus, pixels that are driven by the gate driving circuit may be driven at different frequencies. Further, display areas of a display panel may be driven at different frequencies.

A display device having the gate driving circuit according to example embodiments may drive display areas of the display panel at different frequencies and may have low power consumption.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a display device according to example embodiments.

FIG. 2 is a diagram illustrating a first display area and a second display area of a display panel included in the display device of FIG. 1.

FIG. 3 is a diagram illustrating an example of frequency control signal generated by a frequency control unit included in the display device of FIG. 1.

FIG. 4 is a block diagram illustrating a gate driving circuit included in the display device of FIG. 1.

FIG. 5 is a circuit diagram illustrating an example of an Nth gate driving unit included in the gate driving circuit of FIG. 4.

FIG. 6A is a diagram illustrating an example of a carry signal and a gate signal generated by the gate driving circuit of FIG. 4.

FIG. 6B is a diagram illustrating other example of a carry signal and a gate signal generated by the gate driving circuit of FIG. 4.

FIG. 7 is a circuit diagram illustrating another example of an Nth driving unit included in the gate driving circuit of FIG. 4.

### DETAILED DESCRIPTION OF THE EMBODIMENTS

Hereinafter, the present inventive concept will be explained in detail with reference to the accompanying drawings.

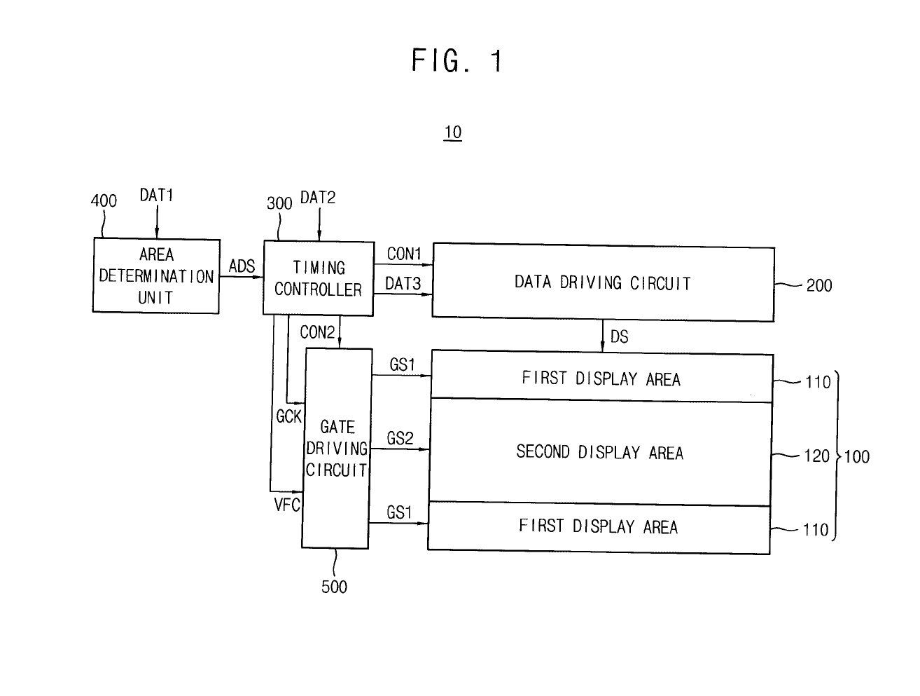

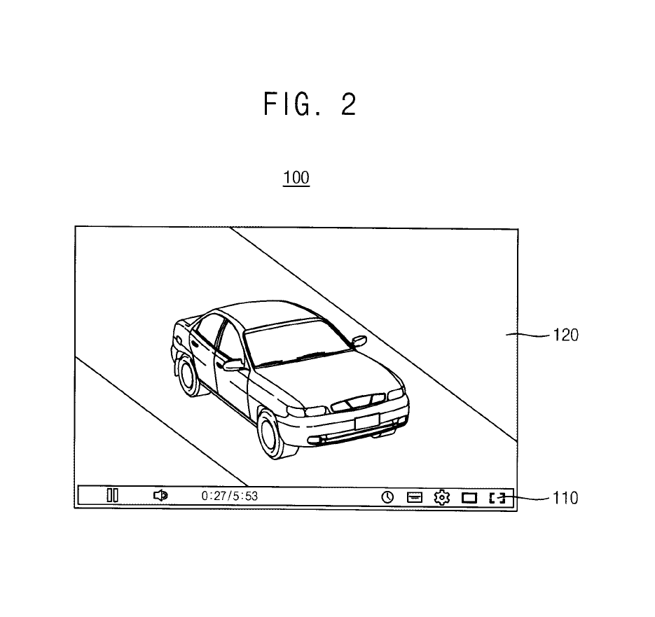

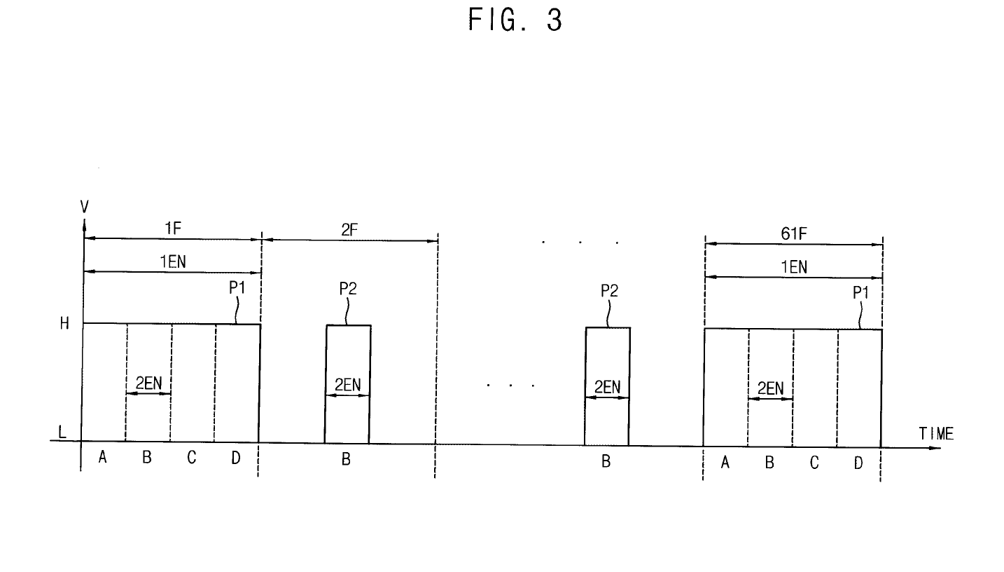

FIG. 1 is a block diagram illustrating a display device according to example embodiments, FIG. 2 is a diagram illustrating a first display area and a second display area of a display panel included in the display device of FIG. 1, and FIG. 3 is a diagram illustrating an example of frequency control signal generated by a frequency control unit included in the display device of FIG. 1.

Referring to FIGS. 1 through 3, a display device 10 may include a display panel 100, a data driving circuit 200, a timing controller 300, an area determination unit 400, and a gate driving circuit 500.

The display device 10 may be a device that displays images based on image data provided from an external device. For example, the display device 10 may be a liquid crystal display device, an organic light emitting display device, a plasma display device, and an electrophoretic display device.

The display panel 100 may include a plurality of gate lines, a plurality of data lines, and a plurality of pixels that disposed in a display area defined by intersections between the gate lines and the data lines. The display panel 100 may include a first display area 110 driven by a first frequency and a second display area 120 driven by a second frequency. In some example embodiments, the first display area 110 may be an area in which a stationary picture is displayed and the second display area 120 may be an area in which a motion picture is displayed. An overall display area of a conventional display panel is driven by the same frequency. For example, when the motion picture is displayed, the overall display area of the conventional display panel may be driven by 60 Hz. Further, when the stationary picture is displayed, the overall display area of the conventional display panel may be driven by some frequency that is lower than 60 Hz. However, the motion picture and the stationary picture may be displayed together depending on a kind of the picture. For example, when the motion picture is displayed, the stationary picture that is a play control button 110 of the motion picture may be displayed in a bottom of the display area as describe in FIG. 2. When the play control button 110 is driven by the same frequency with the motion picture, power consumption may be increased. The display panel 100 according to the example embodiments may divide the display area into a plurality of display areas 110 and 120 that are driven by different frequencies. Thus, the power consumption of the display device 10 may be decreased.

The data driving circuit 200 may provide a data signal DS to the display panel 100. The data driving circuit 200 may include a plurality of shift registers that receives a picture data DAT3 from the timing controller 300 and shifts the picture data DAT3. Each of the shift registers may be coupled to a data line. The shift registers may provide the data signal DS to the display panel 100 through the data line. In some example embodiments, the data driving circuit 200 may be disposed on the display panel 100. In other example embodiments, the data driving circuit 200 may be disposed on a flexible printed circuit board (FPCB) and be coupled to the display panel 100. In other example embodiments, the data driving circuit 200 may be disposed on a printed circuit board (PCB) and be coupled to the display panel 100 through some other connecting lines.

The timing controller 300 may generate a first control signal CON1, a second control signal CON2, a frequency control signal VFC, and a gate clock signal GCK. Further, the timing controller 300 may process a picture data DAT2 received from external device and provide the processed picture data to the data driving circuit 200 corresponding to a predetermined timing. The picture data DAT2 and DAT3 may include the picture data per frame. Further, the picture data DAT2 and DAT3 may include a red image data, a green image data, and a blue image data. The first control signal CON1 is a signal to control an operation of the data driving circuit 200. The data driving circuit 200 may generate the data signal DS in response to the picture data DAT3 and the first control signal CON1. The gate clock signal GCK is a clock signal to generate a gate signal GS1 and GS2. The gate clock signal GCK may include a first gate clock signal and a second gate clock signal. The second gate clock signal may have an on-voltage when the first gate clock signal has an off-voltage and may have the off-voltage when the first gate clock signal has the on-voltage. That is, the second gate clock signal may be an inversion signal of the first gate clock signal. In some example embodiments, the timing controller 300 may provide the gate clock signal GCK to the gate driving circuit 500 corresponding to a master clock signal from an external device. The second control signal CON2 is a signal to control an operation of the gate driving circuit 500. For example, the second control signal CON2 may include a vertical start signal. The gate driving circuit 500 may generate gate signals GS1 and GS2 based on the gate clock signal GCK and the second control signal CON2.

Referring to FIG. 3, the frequency control signal VFC may include a first pulse P1 having an on-voltage H during a first enable period 1EN and a second pulse P2 having an on-voltage H during a second enable period 2EN. The second enable period 2EN may be different from the first enable period 1EN. For example, the first enable period 1EN may be equal to or shorter than one frame period and the second enable period 2EN may be shorter than the first enable period 1EN. Thus, the second enable period 2EN may be included in the first enable period 1EN. In some example embodiments, the first pulse P1 may have an on-voltage H during one frame period. That is, the first enable period 1EN may be substantially the same as one frame period. In some example embodiments, the first pulse P1 may be repeated in a first predetermined cycle. For example, the first pulse P1 may be repeated in every 60 frames. That is, the first pulse P1 has the on-voltage H in the 1st frame 1F and the 61st frame 61F. Further, the first pulse P1 may have the on-voltage H in the 121st frame. When the display panel 100 is driven by 60 Hz, the one frame period may be about one-sixtieth second. The first pulse P1 may have 1 Hz frequency because the first pulse P1 is repeated in every 60 frames. In some example embodiments, the second pulse P2 may have an on-voltage H during the second enable period 2EN. As illustrated in FIG. 3, one frame period may include a plurality of sub-periods A through D. Although, one frame period that includes four sub-periods is illustrated in FIG. 3, the number of the sub-periods is not limited thereto. As illustrated in FIG. 3, the second enable period 2EN may be a B sub-period. In some example embodiments, the second pulse P2 may be repeated in a second predetermined cycle. For example, the second pulse P2 may be repeated in every frame. That is, the second pulse P2 may have the on-voltage H in the B sub-period of the first frame F1, may have the on-voltage in the B sub-period of the second frame F2, and may have the on-voltage in the B sub-period of the third frame 3F. When the display panel 100 is driven by 60 Hz, one frame period may be about one-sixtieth second. The second pulse P2 may have 60 Hz frequency because the second pulse P2 is repeated in every frame. Thus, the frequency control signal VFC may include the first pulse P1 that is repeated in the first cycle having the on-voltage H during the first enable period 1EN and the second pulse P2 that is repeated in the second cycle having the on-voltage H during the second enable period 2EN.

In some example embodiments, the display device 10 may include an area determination unit 400 that divides the display area into a first display area 110 and a second display area 120 based on a picture data DAT1 from the external device. The first display area 110 may be an area in which the stationary picture is displayed. The second display area 120 may be an area in which the motion picture is displayed. The area determination unit 400 may generate an area determination signal ADS to provide the first gate signal GS1 having the first frequency to the first display area 110 and the second gate signal GS2 having the second frequency to the second display area 120. The area determination signal ADS may have an information about a region of the first display area 110 and the second display area 120. The timing controller 300 may generate the frequency control signal VFC in response to the area determination signal ADS. The gate driving circuit 500 may provide a first gate signal GS1 having the first frequency to the first display area 110 and may provide a second gate signal GS2 having the second frequency to the second display area 120 in response to the frequency control signal VFC.

In other example embodiments, the timing controller 300 may perform a function of the area determination unit 400. In this case, the display device 10 may not include the area determination unit 400. The timing controller 300 may divides the display area into a first display area 110 and a second display area 120 based on the picture data DAT2 from the external device.

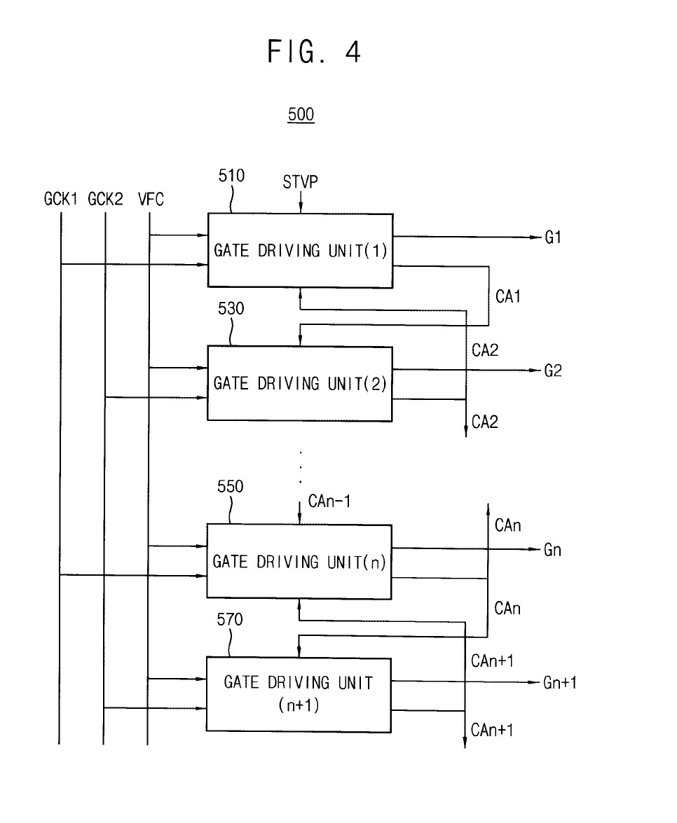

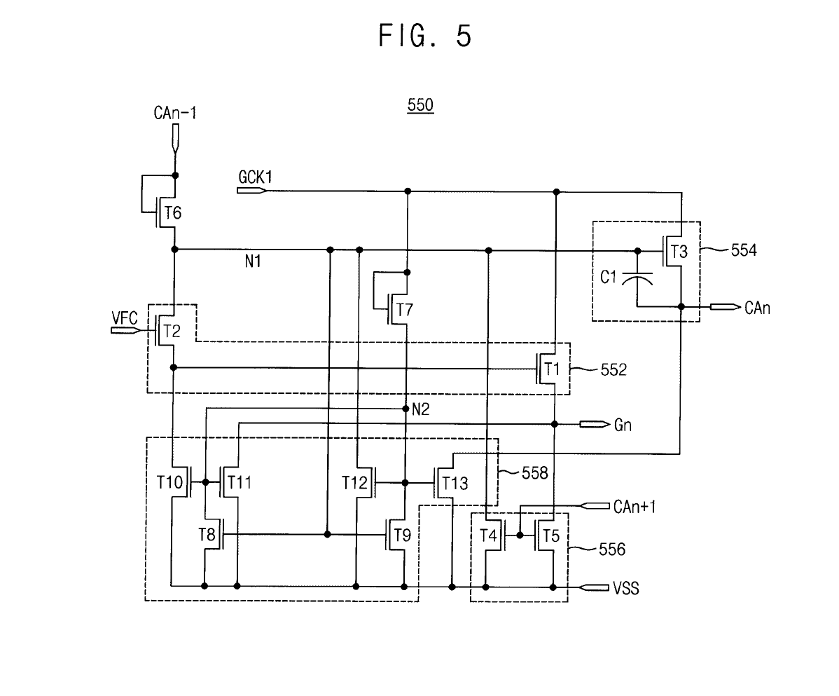

FIG. 4 is a block diagram illustrating a gate driving circuit included in the display device of FIG. 1 and FIG. 5 is a circuit diagram illustrating an example of an Nth gate driving unit included in the gate driving circuit of FIG. 4.

Referring to FIGS. 4 and 5, the gate driving circuit 500 may have a plurality of gate driving units 510, 530, 550, and 570 coupled to the gated lines.

The gate driving units 510, 530, 550, and 570 may be coupled to each other. The gate driving units 510, 530, 550, and 570 may sequentially output gate signals G1 through Gn+1 to the gate lines. Each of the gate driving units 510, 530, 550, and 570 may receive the gate clock signals GCK1 and GCK2 and the frequency control signal VFC. Further, each of the gate driving units 510, 530, 550, and 570 may receive a carry signal CA1 through CAn+1 from the adjacent gate driving units. The gate driving units 510, 530, 550, and 570 may sequentially output the gate signals G1 through Gn+1 to each of the gate lines. Further, the gate driving units 510, 530, 550, and 570 may provide each of the carry signal CA1 through CAn+1 to the previous gate driving unit and the next gate driving unit. For example, the first gate driving unit 510 may generate the first gate signal G1 and the first carry signal CA based on the first gate clock signal GCK1, the vertical start signal STVP, and the frequency control signal VFC. Further, the second gate driving unit 530 may be coupled to the first gate driving unit 510. The second gate driving unit 530 may generate the second gate signal G2 and the second carry signal CA2 based on the first carry signal CA1 and frequency control signal VFC. Here, the second gate clock signal GCK2 may have the off-voltage when the first gate clock signal GCK1 has the on-voltage and may have the on-voltage when the first gate clock signal GCK1 has the off-voltage. That is, the second gate clock signal GCK2 may be the inversion signal of the first gate clock signal GCK1. The Nth gate driving unit 550 may be coupled to the (N−1)th gate driving unit. The Nth gate driving unit 550 may generate the Nth gate signal Gn and the Nth carry signal CAn based on the first gate clock signal GCK1, the (N−1)th carry signal CAn−1, and the frequency control signal VFC. The (N+1)th gate driving unit 570 may be coupled to the Nth gate driving unit 550. The (N+1)th gate driving unit 570 may generate the (N+1)th gate signal Gn+1 and the (N+1)th carry signal CAn+1 based on the second clock signal GCK2, the Nth carry signal CAn, and the frequency control signal VFC. The first gate signal G1 may be provided to the first gate line and drive the pixels of the first row. The second gate signal G2 may be provided to the second gate line and drive the pixels of the second row. The Nth gate signal Gn may be provided to the Nth gate line and drive the pixels of the Nth row. The (N+1)th gate signal Gn+1 may be provided to the (N+1)th gate line and drive the pixels of the (N+1)th row. The carry signals of the gate driving units may be provided to a subsequent gate driving unit. For example, the first carry signal CA1 may be provided to the second gate driving unit 530. The second carry signal CA2 may be provided to the first gate driving unit 510 and the third gate driving unit. The Nth carry signal CAn may be provided to the (N−1)th gate driving unit and the (N+1)th gate driving unit 570. The (N+1)th carry signal CAn+1 may be provided to the Nth gate driving unit 550 and the (N+2)th gate driving unit. Each of the gate signals G1 through Gn+1 may have the first frequency or the second frequency. The gate signals G1 through Gn+1 may have the plurality of pulses that are repeated in predetermined cycles corresponding to each of the frequencies. For example, when the Nth gate line through which the Nth gate signal Gn is provided drives the first display area 110, the Nth gate signal Gn may have the first frequency. That is, the Nth gate signal Gn may include the plurality of pulses that are repeated in the first cycle. When the Nth gate line through which the Nth gate signal Gn is provided drives the second display area 120, the Nth gate signal Gn may have the second frequency. That is the Nth gate signal Gn may include the plurality of pulses that are repeated in the second cycle. The Nth carry signal CAn may have a predetermined frequency. For example, the Nth carry signal CAn may have the frequency that is the same as the driving frequency of the display panel 100. The carry signal CA1 through CAn+1 generated in the gate driving circuit 500 may have the same frequency. Generally, the gate driving circuit 500 may generate the gate signal and the carry signal that have the same frequency. However, the gate driving circuit 500 according to the example embodiments may generate the gate signal G1 through Gn+1 and the carry signal CA1 through CAn+1 that have the different frequencies.

As illustrate in FIG. 5, the gate driving units 510, 530, 550, and 570 may respectively include a pull-up unit 552, a carry unit 554, a pull-down unit 556, and a maintenance unit 558. The Nth gate driving unit 550 will be described below because the composition of the gate driving units 510, 530, 550, and 570 is the same.

The pull-up unit 552 may include a first transistor T1 and a second transistor T2. The first transistor T1 may include an input electrode that receives the first gate clock signal GCK1, an output electrode that outputs the Nth gate signal Gn, and a gate electrode that is coupled to an output electrode of the second transistor T2. The second transistor T2 may include an input electrode that is coupled to a first node N1, the output electrode that is coupled to the gate electrode of the first transistor T1, and a gate electrode that receives the frequency control signal VFC.

The pull-up unit 552 may output the on-voltage of the first gate clock signal GCK1 as the on-voltage of the Nth gate signal Gn. When the first gate clock signal GCK1 has the off-voltage and the (N−1)th carry signal CAn−1 has the on-voltage, the first node N1 may be charged with the on-voltage of the (N−1)th carry signal CAn−1. When the first gate clock signal GCK1 has the on-voltage, the first node N1 may be bootstrapped by the third transistor T3 and a first capacitor C1. When the frequency control signal VFC has the on-voltage, the second transistor T2 may be turned on by the frequency control signal VFC and the first transistor T1 may be turned on by the voltage of the first node N1. Thus, the first transistor T1 may pull up the on-voltage of the first gate clock signal GCK to the on-voltage of the Nth gate signal Gn. Alternatively, when the frequency control signal VFC has the off-voltage, the second transistor T2 may be turned off by the frequency control signal VFC and the Nth gate signal Gn may not be output. As described, the frequency control signal VFC has the on-voltage during the first enable period and the second enable period. Thus, the second transistor T2 may be turned on in the first enable period and the second enable period. Further, the voltage of the first node N1 may be provided to the gate electrode of the first transistor T1 in the first enable period and the second enable period. Thus, the first transistor may be turned on when second transistor T2 is turned on. The period in which the Nth gate signal is output may be defined as an output period.

In some example embodiments, the Nth gate driving unit 550 may further include a pull-up control unit T6 that controls the pull-up unit 552. For example, the pull-up control unit T6 may be a transistor T6 that includes an input electrode receiving the (N−1)th carry signal CAn−1, an output electrode coupled to the first node N1, and gate electrode coupled to the input electrode. The pull-up control unit T6 may charge the first node N1 with the on-voltage of the (N−1)th carry signal CAn−1.

The carry unit 554 may include the first capacitor C1 and a third transistor T3. The third transistor T3 may include an input electrode receiving the first gate clock signal GCK1, an output electrode outputting the Nth carry signal CAn, and a gate electrode coupled to the first node N1. The first capacitor C1 may include a first electrode coupled to the gate electrode of the third transistor T3 and a second electrode coupled to the output electrode of the third transistor T3.

The carry unit 554 may bootstrap the first node N1 and output the on-voltage of the first gate clock signal GCK1 as the on-voltage of the Nth carry signal CAn. When the first gate clock signal GCK1 has the off-voltage, the first node N1 and the first capacitor C1 may be charged with the on-voltage of the (N−1)th carry signal CAn−1. When the first gate clock signal GCK1 has the on-voltage, the third transistor T3 may be turned on and the first node N1 may be bootstrapped by the third transistor T3 and the first capacitor C1. Thus, the on-voltage of the first gate clock signal GCK1 may be output as the on-voltage of the Nth carry signal CAn. The carry unit 554 may always output the Nth carry signal CAn based on the (N−1)th carry signal CAn−1 and the first gate clock signal GCK1 because the carry unit 554 is not be controlled by the frequency control signal VFC.

The pull-down unit 556 may include the fourth transistor T4 and the fifth transistor T5. The fourth transistor T4 may include an input electrode coupled to the first node N1, an output electrode coupled to a low voltage line, and a gate electrode that receives the (N+1)th carry signal CAn+1. The fifth transistor T5 may include an input electrode coupled to the output electrode of the first transistor T1, an output electrode coupled to the low voltage line, and a gate electrode that receives the (N+1)th carry signal CAn+1.

The pull-down unit 556 may pull down the Nth gate signal that is pulled up in response to the (N+1)th carry signal CAn+1 and may discharge the first node N1 to a low voltage. When the (N+1)th carry signal CAn+1 has the on-voltage, the fourth transistor T4 and the fifth transistor T5 may be turned on. Further, the output electrode of the first transistor T1 and the first nod N1 may be pulled down to the low voltage and the Nth gate signal Gn may be pulled down to the off-voltage.

In some example embodiments, the Nth gate driving unit 550 may include a maintenance unit 558. The maintenance unit 558 may include a plurality of transistors T8 through T13. The eighth transistor T8 may include an input electrode coupled to the second nod N2, an output electrode coupled to the low voltage line, and a gate electrode coupled to the first node N1. The ninth transistor T9 may include an input electrode coupled to the second node N2, an output electrode coupled to the low voltage line, and a gate electrode coupled to the first node N1. The tenth transistor T10 may include an input electrode coupled to the gate electrode of the first transistor T1, an output electrode coupled to the low voltage line, and a gate electrode coupled to the second node N2. The eleventh transistor T11 may include an input electrode coupled to the output electrode of the first transistor T1, an output electrode coupled to the low voltage line, and a gate electrode coupled to the second node N2. The twelfth transistor T12 may include an input electrode coupled to the gate electrode of the third transistor T3, an output electrode coupled to the low voltage line, and a gate electrode coupled to the second node N2. The thirteenth transistor T13 may include an input electrode coupled to the output electrode of the third transistor T3, an output electrode coupled to the low voltage line, and a gate electrode coupled to the second node N2.

The maintenance unit 558 may maintain the Nth gate signal Gn in the off-voltage when the Nth gate signal Gn doesn't have the on-voltage. Further, the maintenance unit 558 may maintain the Nth carry signal CAn in the off-voltage when the Nth carry signal CAn doesn't have the on-voltage. When the first node N1 has the on-voltage, the eighth transistor T8 and the ninth transistor T9 may be turned on and the second node N2 is charged with the low voltage. Here, the first transistor T1 and the third transistor T3 may be operated because the tenth through thirteenth transistors T10 through T13 may be turned off. The first transistor T1 and the third transistor T3 may output the Nth gate signal Gn and the Nth carry signal CAn. When the first clock signal has the on-voltage, the second node N2 may have the on-voltage and the tenth through thirteenth transistors T10 through T13 may be turned on. Here, the output electrode and the gate electrode of the first transistor T1 may be maintained in the low voltage VSS. The output electrode and the gate electrode of the first transistor T3 may be maintained in the low voltage VSS. Thus, the Nth gate signal and the Nth carry signal CAn may be maintained in the off-voltage.

In some example embodiments, the Nth gate driving unit 550 may further include the seventh transistor T7 that charges the second node N2 with the on-voltage of the first gate clock signal GCK1. The seventh transistor T7 may include an input electrode that receives the first gate clock signal GCK1, the output electrode coupled to the second node N2, and a gate electrode coupled to the input electrode.

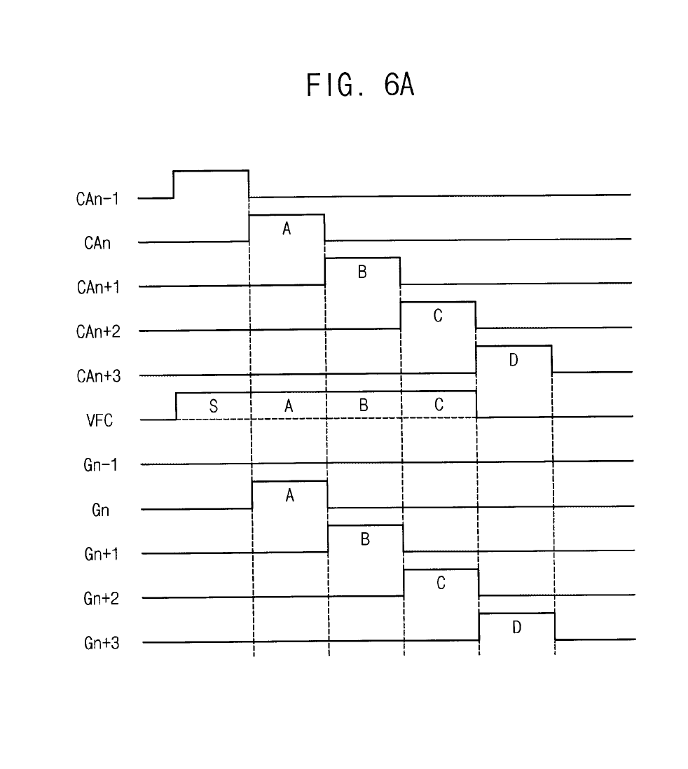

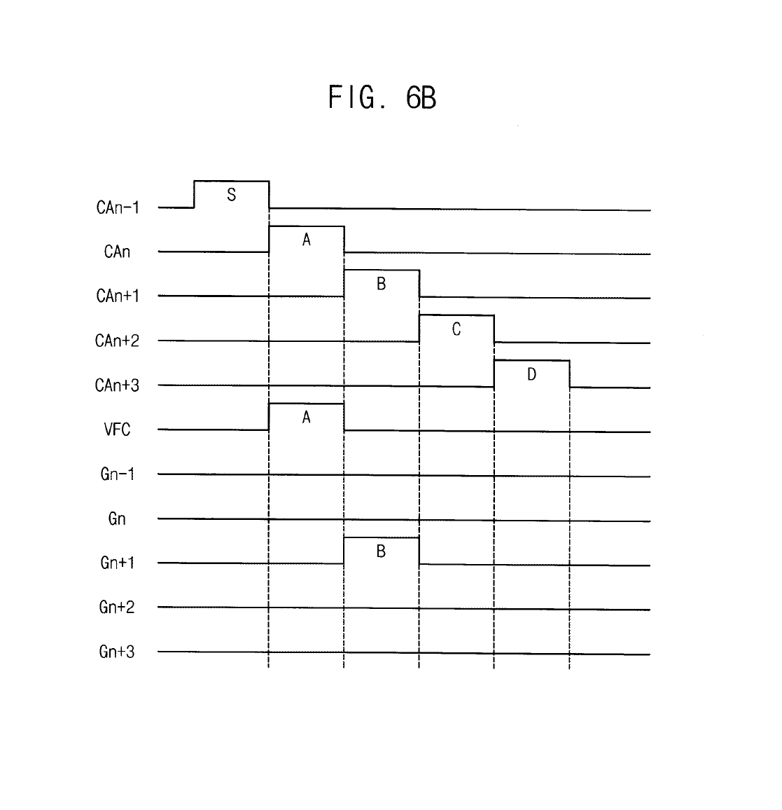

FIG. 6A is a diagram illustrating an example of a carry signal and a gate signal generated by the gate driving circuit of FIG. 4 and FIG. 6B is a diagram illustrating other example of a carry signal and a gate signal generated by the gate driving circuit of FIG. 5.

Referring to FIGS. 6A and 6B, a frequency control signal VFC may control a frequency of a gate signal Gn−1 through Gn+3. For example, the Nth through (N+3)th gate signals Gn through Gn+3 may be output by the frequency control signal VFC having an on-voltage during a first enable period S, A, B, C as illustrated in the FIG. 6A. Further, the gate signals except the Nth through (N+3)th gate signals Gn through Gn+3 may not be output during a first enable period S, A, B, C. In the S period, the first node N2 may be charged with an on-voltage because the (N−1)th carry signal CAn−1 has an on-voltage. Further, in the S period, the second transistor T2 may be turned on by the frequency control signal VFC having an on-voltage. In the A period, when a first gate clock signal GCK1 has an on-voltage, the first node N1 may be bootstrapped, and the first transistor T1 may be turned on by the voltage of the first node N1. Thus, the Nth gate signal Gn may be output in the A period. That is, the Nth gate signal Gn may be output in the A period that is the next period of the S period by the frequency control signal VFC that has the on-voltage in the S period. The (N+1)th gate driving unit 570 that is coupled to the Nth gate driving unit 550 may generate the (N+1)th carry signal CAn+1 based on the Nth carry signal CAn and the second gate clock signal GCK2. In the B period that is next period of the A period, the (N+1)th gate signal Gn+1 may be output because the frequency control signal VFC still has the on-voltage in the A period in which the Nth carry signal CAn has the on-voltage. The (N+2)th gate driving unit that is coupled to the (N+1)th gate driving unit 570 may generate the (N+2)th carry signal CAn+2 based on the (N+1)th carry signal CAn+1 and the first gate clock signal GCK1. In the C period that is the next period of the B period, the (N+2)th gate signal Gn+2 may be output because the frequency control signal VFC still has the on-voltage in the B period in which the (N+1)th carry signal CAn+1 has the on-voltage. The (N+3)th gate driving unit that is coupled to the (N+2)th gate driving unit may generate the (N+3)th carry signal CAn+3 based on the (N+2)th carry signal CAn+2 and the second gate clock signal GCK2. In the D period that is the next period of the C period, the (N+3)th gate signal Gn+3 may be output because the frequency control signal VFC still has the on-voltage in the C period in which the (N+2)th carry signal CAn+2 has the on voltage. The (N+4)th gate driving unit that is coupled to the (N+3)th gate driving unit may generate the (N+4)th carry signal based on the (N+3)th carry signal CAn+3 and the first gate clock signal GCK1. However, in the next period of the D period, the (N+4)th gate signal Gn+4 may not be output because the frequency control signal VFC has an off-voltage in the D period in which the (N+3)th carry signal has the on-voltage. In conclusion, the gate signal Gn−1 through Gn+3 may be output in the output period A, B, C, and D. The output period A, B, C, and D may have substantially the same width as the enable period S, A, B, and C in which the frequency control signal VFC has the on-voltage. However, the output period A, B, C, and D may be shifted. For example, the output period A, B, C, and D may be shifted by a predetermined time, i.e. S period, from a start time of the enable period S, A, B, and C.

As illustrated in FIG. 6B, when the frequency control signal VFC has the on-voltage in the A period, the gate signal Gn+1 may be output in the B period that is the next period of the A period. That is, the output period B may be shifted by a predetermined time, i.e. A period from the enable period A of the frequency control signal VFC. Only (N+1)th gate driving unit 570 may output the (N+1)th gate signal Gn+1 by the frequency control signal VFC because the B period is a period in which the (N+1)th gate signal Gn+1 is output. However, the gate driving unit 510, 530, 550, and 570 may respectively output the carry signals CAn−1 through CAn+3 regardless of the frequency control signal VFC.

Referring to FIG. 3, each of the gate signals Gn−1 through Gn+3 may be repeated in the different cycle because the frequency control signal VFC includes the first pulse P1 that is repeated in the first cycle and the second pulse P2 that is repeated in the second cycle. For example, the (N+2)th gate driving unit that outputs the carry signal having the on-voltage in the C period that is the next period of the B period may output the gate signal Gn+2 in every frame period because the on-voltage is output in the B period of every frame period.

Alternatively, the gate driving units that outputs the carry signal having the on-voltage in the B, D, and A period that is the next period of the A, C, and D period may output the gate signals in every 60 frames because the frequency control signal VFC has the on-voltage in the A, C, and D period in every 60 frames except the B period. Thus, the pixels that are driven by the (N+2)th gate driving unit may receive the data signals in every frame and the other pixels that are driven by the other gate driving units may receive the data signals in every 60 frame. That is, the pixels that are driven by the (N+2)th gate driving unit may be driven by the driving frequency of the display panel 100 and the other pixels that are driven by the other gate driving units may be driven by the frequency that is smaller than the driving frequency of the display panel 100.

As described, each of the gate driving units 510, 530, 550, and 570 that are included in the gate driving circuit 500 may include the pull-up unit 552 controlled by the frequency control signal VFC. The gate driving units 510, 530, 550, and 570 may output the gate signals G1 through Gn+1 of which frequencies are different from each other because the frequency control signal VFC includes the first pulse P1 and the second pulse P2 of which frequencies are different. Thus, the pixels that are driven by the gate driving units 510, 530, 550, and 570 may be driven by different frequencies. Further, the display device 10 that includes the gate driving circuits 500 may have low power consumption because the display area of the display panel 100 are driven by different frequencies by the gate driving circuit 500.

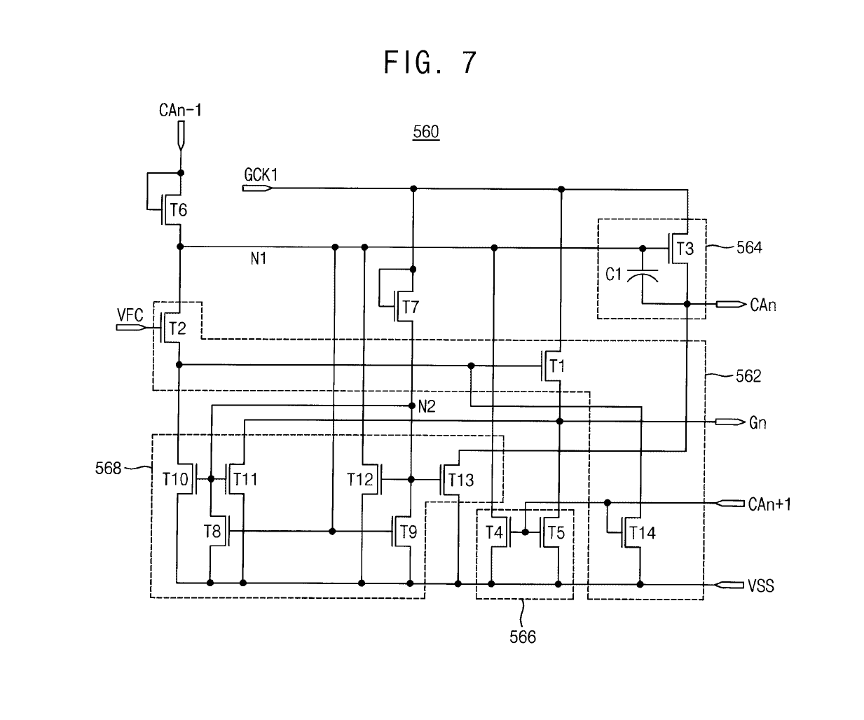

FIG. 7 is a circuit diagram illustrating another example of an Nth gate driving unit included in the gate driving circuit of FIG. 4.

Referring to FIG. 7, the gate driving circuit 500 may include a plurality of gate driving units. The Nth gate driving unit 560 of the gate driving units is illustrated in FIG. 7. The Nth gate driving unit 560 will be described below because the composition of the gate driving units is the same.

The Nth gate driving unit 560 may include the pull-up unit 562, the carry unit 564, the pull-down unit 566, and the maintenance unit 568. The carry unit 564, the pull-down unit 566, and the maintenance unit 568 illustrated in FIG. 7 may be substantially the same as the described in FIG. 5.

The pull-up unit 562 may include a first transistor T1, a second transistor T2, and an initialization transistor T14. The first transistor T1 may include an input electrode that receives the first gate clock signal GCK1, an output electrode that outputs an Nth gate signal Gn, and a gate electrode coupled to an output electrode of the second transistor T2. The second transistor T2 may include an input electrode coupled to a first node N1, the output electrode coupled to the gate electrode of the first transistor T1, and a gate electrode that receive a frequency control signal VFC. The initialization transistor T14 may include an input electrode coupled to the gate electrode of the first transistor T1, an output electrode coupled to the low voltage Vss, and a gate electrode that receives a (N+1)th carry signal CAn+1.

The pull-up unit 552 may output an on-voltage of a first gate clock signal GCK1 as an on-voltage of an Nth gate signal Gn. The output process of the Nth gate signal Gn is substantially the same as described above.

The initialization transistor T14 may initialize the gate electrode of the first transistor T1 to a low voltage VSS in response to an (N+1)th carry signal CAn+1. As described, the Nth gate signal Gn may be output when the first gate clock signal GCK1 has the on-voltage. The initializing process of gate electrode of the first transistor T1 is required to improve the reliability. Thus, the initialization transistor T14 may initialize the gate electrode of the first transistor T1 to the low voltage VSS in response to the (N+1)th carry signal CAn+1 that has the on-voltage in the pull-down period. The pull-up unit 562 may stably provide the Nth gate signal Gn by including the initial transistor T14.

As described, each of the gate driving units 560 included in the gate driving circuit may have the pull-up unit 562 controlled by the frequency control signal VFC, and the frequency control signal VFC may include the first pulse and the second pulse of which frequencies are different. Thus, the gate driving units 560 may output the gate signals Gn of which frequencies are different. The pixels that are driven by the respective gate driving units 560 may be driven by different frequencies. Further, the reliability of the gate driving units 560 that include the pull-up units 562 having the initialization transistor T14 may be improved. The display device that includes the gate driving circuits may have low power consumption because the display areas of the display panel are driven by different frequencies by the gate driving circuit 500.

The present inventive concept may be applied to a display device having a display panel. For example, the present inventive concept may be applied to a computer monitor, a laptop, a digital camera, a cellular phone, a smart phone, a smart pad, a television, a personal digital assistant (PDA), a portable multimedia player (PMP), a MP3 player, a navigation system, a game console, a video phone, etc.

The foregoing is illustrative of example embodiments and is not to be construed as limiting the scope of appended claims. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A gate driving circuit including a plurality of gate driving units respectively coupled to a plurality of gate lines, each of the plurality of gate driving units comprising:
a carry unit configured to output a carry signal;
a pull-up unit configured to output a gate signal in response to a frequency control signal, the frequency control signal including a first pulse having an on-voltage during a first enable period and a second pulse having an on-voltage during a second enable period that is different from the first enable period, the first pulse being repeated in a first cycle, and the second pulse being repeated in a second cycle that is different from the first cycle, the frequency control signal being configured to controlling a frequency of outputting the gate signal; and
a pull-down unit configured to pull down an output node of the gate signal.

2. The gate driving circuit of claim 1, wherein the second enable period of the second pulse is shorter than the first enable period of the first pulse, and
wherein the second cycle of the second pulse is shorter than the first cycle of the first pulse.

3. The gate driving circuit of claim 2, wherein the first enable period of the first pulse is equal to or shorter than a frame period.

4. The gate driving circuit of claim 3, wherein the gate signal is output in a first output period having substantially the same width as the first enable period and in a second output period having substantially the same width as the second enable period,
wherein the first output period is delayed by a predetermined first time period from a start timing of the first enable period, and
wherein the second output period is delayed by the predetermined first time period from a start timing of the second enable period.

5. The gate driving circuit of claim 4, wherein the frequency control signal has an on-voltage when the gate clock signal has the on-voltage.

6. The gate driving circuit of claim 1,
wherein the pull-up unit includes:
a first transistor having an input electrode that receives a gate clock signal and an output electrode that outputs the gate signal; and
a second transistor having an input electrode coupled to a first node and an output electrode coupled to a gate electrode of the first transistor, the second transistor being configured to output a voltage of the first node to the gate electrode of the first transistor in the first and second enable periods in response to the frequency control signal.

7. The gate driving circuit of claim 6, wherein the pull-up unit further includes:
an initialization transistor having an input electrode coupled to the gate electrode of the first transistor, an output electrode coupled to a low voltage line, and a gate electrode that receives a carry signal from a subsequent gate driving unit,
wherein the initialization transistor initializes the gate electrode of the first transistor to a low voltage in response to the carry signal from the subsequent gate driving unit.

8. The gate driving circuit of claim 6, wherein the gate driving unit further includes:
a pull-up control transistor having an input electrode that receives the carry signal from a previous gate driving unit, an output electrode coupled to the first node, and a gate electrode coupled to the input electrode of the pull-up control transistor,
wherein the pull-up control transistor charges the first node to an on-voltage of the carry signal from a previous gate driving unit in response to the carry signal from a previous gate driving unit.

9. The gate driving circuit of claim 1, wherein the carry unit includes:
a third transistor having an input electrode that receives a gate clock signal, an output electrode that outputs the carry signal, and a gate electrode coupled to a first node; and
a first capacitor disposed between the gate electrode of the third transistor and the output electrode of the third transistor.

10. The gate driving circuit of claim 1, wherein the pull-down unit includes:
a fourth transistor having an input electrode coupled to a first node, an output electrode coupled to a low voltage line, and a gate electrode that receives the carry signal from a subsequent gate driving unit, the fourth transistor configured to pull down the voltage of the first node to a low voltage in response to the carry signal from a subsequent gate driving unit; and
the fifth transistor having an input electrode coupled to the output electrode of the first transistor, an output electrode coupled to the low voltage line, and a gate electrode that receives the carry signal from a subsequent gate driving unit, the fifth transistor configured to pull down the on-voltage of the gate signal to an off-voltage in response to the carry signal from a subsequent gate driving unit.

11. A display device comprising:
a display panel having a plurality of gate lines, a plurality of data lines, and a plurality of pixels coupled to the plurality of gate lines and the data lines, the display panel including a first display area that is driven at a first frequency and a second display area that is driven at a second frequency that is different from the first frequency;
a data driving circuit coupled to the data lines, the data driving circuit being configured to provide data signals to the data lines;
a timing controller configured to control the data driving circuit, and to generate a frequency control signal and a gate clock signal, the frequency control signal including a first pulse having an on-voltage during a first enable period and a second pulse having an on-voltage during a second enable period that is different from the first period, the first pulse being repeated in a first cycle, and the second pulse being repeated in a second cycle that is different from the first cycle; and
a gate driving circuit configured to receive the gate clock signal and the frequency control signal from the timing controller, to provide the first display area with a first gate signal with the first frequency based on the gate clock signal and the first pulse of the frequency control signal, and to provide the second display area with a second gate signal with the second frequency based on the gate clock signal and the second pulse of the frequency control signal.

12. The display device of claim 11, wherein the second enable period of the second pulse is shorter than the first enable period of the first pulse, and
wherein the second cycle of the second pulse is shorter than the first cycle of the first pulse.

13. The display device of claim 12, wherein the first enable period of the first pulse is equal to or shorter than a frame period.

14. The display device of claim 13, wherein the first gate signal is output in a first output period having substantially the same width as the first enable period,
wherein the second gate signal is output in a second output period having substantially the same width as the second enable period,
wherein the first output period is delayed by a predetermined first time period from a start timing of the first enable period, and
wherein the second output period is delayed by the first time period from a start timing of the second enable period.

15. The display device of claim 14, wherein the timing controller generates the frequency control signal having an on-voltage when the gate clock signal has the on-voltage.

16. The display device of claim 11, wherein the gate driving circuit includes a plurality of gate driving units, each of the plurality of gate driving units includes:
a carry unit configured to charge a first node in response to a carry signal from a previous gate driving unit and configured to output a carry signal;
a pull-up unit configured to output the gate clock signal as the first or second gate signal in response to the frequency control signal; and
a pull-down unit configured to pull down an output node of the gate signal to an off-voltage in response to a carry signal received from a subsequent gate driving unit.

17. The display device of claim 16, wherein the pull-up unit includes:
a first transistor having an input electrode that receives the gate clock signal and an output electrode that outputs a first or second gate signal; and
a second transistor having an input electrode coupled to the first node and an output electrode coupled to a gate electrode of the first transistor, the second transistor configured to output a voltage of the first node to the gate electrode of the first transistor in the first and second enable periods in response to the frequency control signal.

18. The display device of claim 17, wherein the pull-up unit further includes:
an initialization transistor having an input electrode coupled to the gated electrode of the first transistor, an output electrode coupled to a low voltage line, and a gate electrode that receives the carry signal from the subsequent gate driving unit,
wherein the initialization transistor initializes the gate electrode of the first transistor to a low voltage in response to the carry signal from the subsequent gate driving unit.

19. The display device of claim 17, wherein the gate driving unit further includes:
a pull-up control transistor having an input electrode that receives the carry signal from the previous gate driving unit, an output electrode coupled to the first node, and a gate electrode coupled to the input electrode of the pull-up control transistor,
wherein the pull-up control transistor charges the first node to the on-voltage of the previous carry signal in response to the carry signal from the previous gate driving unit.

20. The display device of claim 11, further comprising:
an area determination unit determining the first display area and the second display area based on a picture data,
wherein the timing controller receives an area determination signal from the area determination unit and generates the frequency control signal.
